(19) United States
(12) Patent Application Publication
(10) Pub. No.: US 2011/0171834 A1
(43) Pub. Date: Jul. 14, 2011

(54) SILICON ETCHANT AND ETCHING METHOD

(75) Inventors: Kazuyoshi Yaguchi, Tokyo (JP); Ryuji Sotoaka, Tokyo (JP)

(73) Assignee: Mitsubishi Gas Chemical Company, Inc., Tokyo (JP)

(21) Appl. No.: 13/055,991

(22) PCT Filed: Jun. 25, 2009
(86) PCT No.: PCT/JP09/61619

§ 371 Date: Jan. 28, 2011

(30) Foreign Application Priority Data
Jul. 28, 2008 (JP) 2008-193092

(51) Int. Cl. H01L 21/306; C09K 13/00

(52) U.S. Cl. 438/753; 252/79.1; 257/E21.219

(57) ABSTRACT

In etching processing of silicon, in particular anisotropic etching processing of silicon in a manufacturing step of MEMS parts, an etchant having a long life of etchant and an etching method are provided by suppressing a lowering of an etching rate at the time of warming which is characteristic of a hydroxylamine-containing etchant.

A silicon etchant for anisotropically dissolving monocrystalline silicon therein, which is an alkaline aqueous solution containing (A) tetramethylammonium hydroxide, (B) hydroxylamine and (C) carbon dioxide (CO₂) and/or a carbonic acid salt of tetramethylammonium and having a pH of 13 or more, and an etching method of silicon using this etchant are provided.

### TECHNICAL FIELD

The present invention relates to etching processing of silicon. In particular, the present invention relates to a silicon etchant and a silicon etching method to be used for manufacturing parts used for MEMS (Micro-Electro-Mechanical System), so-called micromachines, or semiconductor devices.

### BACKGROUND ART

In general, in the case where a silicon single crystal substrate is etched with a chemical solution, a method of performing etching with an acidic etchant which is a mixed aqueous solution having components such as hydrofluoric acid and nitric acid, etc. added thereto; or a method of performing etching with an alkaline etchant which is an aqueous solution of potassium hydroxide (KOH), tetramethylammonium hydroxide (TMAH), etc. is carried out (see Non-Patent Documents 1 and 2).

In the case where an acidic etchant is used, the surface of silicon is oxidized with a component having an oxidizing action, such as nitric acid, etc., to form silicon oxide, and this silicon oxide is dissolved as silicon fluoride by hydrofluoric acid, etc., whereby etching proceeds. A characteristic feature on the occasion of performing etching with an acidic etchant resides in the matter that even when silicon which is an etching object is monocrystalline, polycrystalline or amorphous, the etching isotropically proceeds. For that reason, on the occasion of performing pattern etching using a pattern mask, etc., there may be the case where the deeper the etching is, the more the etching in a lateral direction, namely undercut (erosion) beneath the pattern mask proceeds to the same degree as the depth, resulting in causing inconvenience.

On the other hand, in the case where an alkaline etchant is used, silicon is dissolved as a silicate ion by a hydroxy anion in the liquid, and on that occasion, water is reduced to generate hydrogen. When etching with the alkaline etchant is performed, different from the acidic etchant, etching of monocrystalline silicon proceeds while keeping anisotropy. This is based on the matter that there is a difference in a dissolution rate of silicon in every crystal face orientation of silicon, and this etching is also called crystal anisotropic etching. Even in polycrystalline silicon, etching proceeds while keeping anisotropy on microscopic observations. However, in view of the fact that the face orientation of crystal grains is randomly distributed, isotropic etching appears to proceed on macroscopic observations. In amorphous silicon, etching isotropically proceeds on both of microscopic observations and macroscopic observations.

In addition to the aqueous solution of KOH or TMAH, an aqueous solution of sodium hydroxide (NaOH), ammonia, hydrazine, etc. is used as the alkaline etchant. In etching processing of a monocrystalline silicon substrate using such an aqueous solution, in many cases, a long processing time of from several hours to several ten hours is required, an aspect of which, however, varies depending upon a desired processing shape or a temperature condition for performing the treatment or the like.

For the purpose of shortening this processing time even a little, chemical solutions exhibiting a high etching rate are developed. For example, Patent Document 1 discloses a technology of using, as an etchant, an aqueous solution having a hydroxylamine added to TMAH. Also, Patent Document 2 discloses a technology of using, as an etchant, an aqueous solution having a specified compound such as iron, iron (III) chloride, iron (II) hydroxide, etc. added to TMAH and discloses that so far as a degree of the effect for making the etching rate fast is concerned, a combined use of iron and a hydroxylamine is especially suitable. Also, Patent Document 3 discloses a technology of using, as an etchant, an aqueous solution having a hydroxylamine added to KOH.

[Patent Document 1] JP-A-2006-054363

[Patent Document 2] JP-A-2006-186329

[Patent Document 3] JP-A-2006-351813

[Non-Patent Document 1] Sato, “Silicon Etching Technologies” in Journal of the Surface Finishing Society of Japan, The Surface Finishing Society of Japan, Vol. 51, No. 8, 2000, pages 754 to 759

[Non-Patent Document 2] Esashi, 2003 MEMS Technology Outlook, Electronic Journal, Inc., Jul. 25, 2003, pages 109 to 114

### DISCLOSURE OF THE INVENTION

### Problem that the Invention is to Solve

However, in view of the fact that the hydroxylamine which is added for the purpose of accelerating the etching rate in the technologies described in the foregoing Patent Documents 1, 2 and 3 is a self-decomposing compound, a lowering of concentration to be caused due to denaturation during the storage at room temperature is easy to occur, and in the case where the etchant per se is kept in a warmed state, the lowering of concentration becomes much more conspicuous. Since this lowering of concentration of the hydroxylamine causes a lowering of the etching rate, when kept in a warmed state, the etching rate is lowered with a lapse of time. For that reason, in the case of performing etching processing so as to form deep pores using a hydroxylamine-containing etchant, a complicated operation of repeated confirmation to what extent of depth the etching processing proceeds was needed.

Then, an object of the present invention is to provide a silicon etchant capable of anisotropically dissolving monocrystalline silicon therein while depressing a lowering of an etching rate with a lapse of time by suppressing the decomposition of hydroxylamine without impairing a strong point of a hydroxylamine-containing alkaline aqueous solution such that the etching rate is high and a silicon etching method.

### Means for solving the Problems

In order to solve the foregoing problems, the present inventors made extensive and intensive investigations. As a result, it has been found that by performing etching with an alkaline aqueous solution containing tetramethylammonium hydroxide, hydroxylamine and carbon dioxide and/or a carbonic acid salt of tetramethylammonium and having a pH of 13 or more, a lowering of the etching rate to be caused due to the decomposition of hydroxylamine can be suppressed without impairing a strong point such that the etching rate against silicon is high, leading to accomplishment of the present invention.

That is, the present invention is concerned with a silicon etchant and an etching method, and the gist thereof is as follows.

1. A silicon etchant for anisotropically dissolving monocrystalline silicon therein, comprising an alkaline aqueous solution containing (A) tetramethylammonium hydroxide, (B) hydroxylamine and (C) carbon dioxide (CO₂) and/or a carbonic acid salt of tetramethylammonium and having a pH of 13 or more.

2. The silicon etchant as set forth above in 1, wherein the carbonic acid salt of tetramethylammonium (C) is one or more members selected from tetramethylammonium carbonate [{(CH₃)₄N}₂CO₃] and tetramethylammonium hydrogencarbonate [{(CH₃)₄N}HCO₃]. 3. The silicon etchant as set forth above in 1, wherein an amount of a tetramethylammonium ion {(CH₃)₄N⁺} derived from the tetramethylammonium hydroxide (A) and the carbonic acid salt of tetramethylammonium (C) contained in the silicon etchant is in the range of from 1.0 mole to 2.4 moles per kg of the silicon etchant; and a total sum of a carbonate ion (CO₃²⁻) and a hydrogencarbonate ion (HCO₃⁻) derived from the carbon dioxide (CO₂) and carbonic acid salt of tetramethylammonium (C) is in the range of from 0.28 to 0.42 in terms of a molar ratio relative to the amount of the tetramethylammonium ion.

4. The silicon etchant as set forth above in any one of 1 to 3, wherein a pH is 13.3 or more.

5. A silicon etching method for anisotropically dissolving monocrystalline silicon therein, comprising using an alkaline aqueous solution containing (A) tetramethylammonium hydroxide, (B) hydroxylamine and (C) carbon dioxide (CO₂) and/or a carbonic acid salt of tetramethylammonium and having a pH of 13 or more.

6. The silicon etching method as set forth above in 5, wherein a step of brining the alkaline aqueous solution and an etching object into contact with each other is included.

7. The silicon etching method as set forth above in 5 or 6, wherein the carbonic acid salt of tetramethylammonium (C) is one or more members selected from tetramethylammonium carbonate [{(CH₃)₄N}₂CO₃] and tetramethylammonium hydrogencarbonate [{(CH₃)₄N}HCO₃].

### ADVANTAGE OF THE INVENTION

According to the invention of the present application, it is possible to provide a silicon etchant for anisotropically dissolving monocrystalline silicon therein and a silicon etching method, in which while keeping a high etching rate as a strong point of the hydroxylamine-containing alkaline aqueous solution, not only the decomposition of hydroxylamine can be suppressed, but a lowering of the etching rate can be suppressed. In consequence, complicated operations such as frequent processing shape confirmation in realizing a long life of the hydroxylamine-containing silicon etchant and performing an etching treatment, and the like can be greatly simplified.

### BEST MODES FOR CARRYING OUT THE INVENTION

### [Silicon Etchant]

The silicon etchant of the present invention is an alkaline aqueous solution containing (A) tetramethylammonium hydroxide, (B) hydroxylamine and (C) carbon dioxide (CO₂) and/or a carbonic acid salt of tetramethylammonium and having a pH of 13 or more and is a silicon etchant for anisotropically dissolving monocrystalline silicon therein. First of all, each composition of the silicon etchant of the present invention is described.

### <<(A) Tetramethylammonium Hydroxide>>

The tetramethylammonium hydroxide (A) which is used in the present invention is a strongly basic compound composed of a tetramethylammonium ion as a cation and a hydroxide ion (OH⁻) as an anion. In general, the tetramethylammonium hydroxide is commercially available as aqueous solutions of various concentrations of from about 2% to 25%.

<<(C) Carbon Dioxide (CO₂) and/or Carbonic Acid Salt of Tetramethylammonium>>

The carbon dioxide (CO₂) and/or the carbonic acid salt of tetramethylammonium, each of which is used in the present invention, is a compound which, when dissolved in water, generates a carbonate ion (CO₃²⁻) or a hydrogencarbonate ion (HCO₃⁻) (hereinafter sometimes referred to as “water-soluble carbonate compound”). Then, in the present invention, as a matter of course, the carbonic acid salt of tetramethylammonium includes tetramethylammonium carbonate [{(CH₃)₄N}₂CO₃], and it may also include tetramethylammonium hydrogencarbonate [{(CH₃)₄N}HCO₃].

### <<pH of Etchant>>

The silicon etchant of the present invention is required to have a pH of 13 or more. This is because when the pH is less than 13, the etching rate of silicon is extremely lowered. The present invention is concerned with a silicon etchant exhibiting a high etching rate in view of the fact that it contains hydroxylamine and is one aiming at keeping this high etching rate for a long period of time as far as possible. When the etching rate itself is extremely lowered, thereby specifically becoming in a state where there is no significant difference from the case where hydroxylamine is not added, the matter itself of keeping the etching rate for a long period of time as far as possible becomes meaningless. In consequence, it is necessary to regulate the pH value to 13 or more such that the etching rate is not lowered. From such a viewpoint, the pH of the silicon etchant of the present invention is preferably 13.3 or more.

In general, as shown in the following reaction formulae (1) and (2), the carbonate ion in the aqueous solution is in an equilibrium state with the hydrogencarbonate ion, and furthermore, the hydrogencarbonate ion is in an equilibrium state with carbon dioxide (Christian's Analytical Chemistry I: Basic Edition, supervised and translated by Haraguchi, Maruzen Co., Ltd., 2005, p.309). When the pH value increases, namely the OH⁻ concentration increases, the equilibrium of (2) moves toward the left-side direction, and furthermore, the equilibrium of (1) also moves toward the left-side direction. That is, by increasing the pH, it is possible to convert not only carbon dioxide but the hydrogencarbonate ion into the carbonate ion.

Also, in the silicon etchant of the present invention, a tetramethylammonium ion [{(CH₃)₄N}⁻] is generated resulting from tetramethylammonium hydroxide, and in the case where carbonic acid salt of tetramethylammonium is used, a tetramethylammonium ion [{(CH₃)₄N}⁻] is generated resulting from the subject carbonic acid salt of tetramethylammonium.

CO₃²⁻+H₂O⇄HCO₃⁻+OH⁻ (1)

HCO₃⁻H₂O⇄CO₂+H₂O+OH⁻ (2)

The carbon dioxide (CO₂) or the carbonic acid salt of tetramethylammonium such as tetramethylammonium carbonate, tetramethylammonium hydrogencarbonate, etc., each of which is used in the present invention, may be used singly or in combinations. This is because regardless of whether the added material is carbon dioxide or tetramethylammonium hydrogencarbonate, so far as the equilibrium moves by an increase of the pH value, it is converted into the form of a carbonate ion. Even when the added water-soluble carbonate compound is carbon dioxide or tetramethylammonium hydrogencarbonate, by regulating the pH value, it is possible to prepare a silicon etchant equal to that prepared by adding tetramethylammonium carbonate as a result.

An amount of the tetramethylammonium ion contained in the silicon etchant of the present invention is preferably in the range of from 1.0 mole to 2.4 moles, and more preferably in the range of from 1.1 moles to 2.3 moles per kg of the silicon etchant. When the amount of the tetramethylammonium ion contained per kg of the silicon etchant is in the concentration range higher than 1.0 mole, an effect for enhancing the etching rate by hydroxylamine is sufficiently obtained. Also, when it is in the concentration range lower than 2.4 moles, the amount of the water-soluble carbonate compound necessary for suppressing the decomposition of hydroxylamine becomes low, and the total concentration of dissolved components in the etchant becomes low; and thus, a silicate is not deposited by dissolution of a relatively small amount of silicon, and handing is easy.

Furthermore, a total sum of the carbon dioxide (CO₂), the carbonate ion (CO₃²⁻) and the hydrogencarbonate ion (HCO₃⁻), each of which is derived from the water-soluble carbonate compound, is preferably in the range of from 0.28 to 0.42 in terms of a molar ratio relative to the amount of the tetramethylammoniumion. In the concentration range where the subject molar ratio is higher than 0.28, an effect for suppressing the decomposition of hydroxylamine is sufficiently obtained, and a lowering of the etching rate can be easily suppressed. Also, In the concentration range where the molar ratio is lower than 0.42, a lowering of the etching rate following a lowering of the pH value is not caused.

In the present invention, the tetramethylammonium ion concentration and the molar ratio of the total sum of the carbon dioxide (CO₂), the carbonate ion (CO₃²⁻) and the hydrogencarbonate ion (HCO₃⁻) relative to the amount of the tetramethylammonium ion are values determined according to the calculation from the amounts of the added tetramethylammonium hydroxide and water-soluble carbonate compound. That is, so far as the silicon etchant of the present invention falls within the pH range, the subject ion concentration and molar ratio can be calculated on the assumption that the water-soluble carbonate compound added in the aqueous solution is present upon being completely dissociated.

### <<(B) Hydroxylamine>>

A concentration of hydroxylamine which is used in the present invention can be properly determined depending upon a desired silicon etching rate, and hydroxylamine is preferably used in a concentration in the range of from 1 to 11% by weight. When the concentration of hydroxylamine is lower than 1% by weight, there may be the case where the effect for enhancing the silicon etching rate due to the addition of hydroxylamine is not distinctly obtained. When it is 1% by weight or more, the effect for enhancing the etching rate due to the addition of hydroxylamine is distinctly obtained. On the occasion of increasing the hydroxylamine concentration, there is found a tendency that following this, the etching rate monotonously increases, too. However, even by increasing the concentration of hydroxylamine exceeding 11% by weight, an effect for further enhancing the etching rate is small. The hydroxylamine concentration may be properly determined while taking into consideration a desired etching rate.

### [Silicon Etching Method]

The silicon etching method of the present invention is a silicon etching method for anisotropically dissolving monocrystalline silicon therein, comprising using a silicon etchant of the present invention, that is, an alkaline aqueous solution containing (A) tetramethylammonium hydroxide, (B) hydroxylamine and (C) carbon dioxide (CO₂) and/or a carbonic acid salt of tetramethylammonium and having a pH of 13 or more. Then, a more preferred embodiment of the silicon etching method of the present invention is one including a step of brining the silicon etchant of the present invention into contact with an etching object.

A method of bringing the silicon etchant into contact with the etching object is not particularly limited, and for example, a method of bringing the silicon etchant into contact with the object by a mode such as dropping (single-wafer spin processing), spraying, etc., a method of immersing the object in the silicon etchant and the like can be adopted. In the present invention, a method of bringing the silicon etchant into contact with the object by dropping (single-wafer spin processing) or a method of bringing the object into contact with the silicon etchant upon being immersed is preferably adopted.

More specifically, a method including a contact step of immersing the object in the warmed etchant or bringing the subject etchant into contact with the object, a rinse step of after a lapse of a prescribed time, taking out the object and rinsing off the etchant attached to the object with water or the like and a drying step of subsequently drying the attached water is preferably adopted as the silicon etching method of the present invention.

A use temperature of the etchant is preferably a temperature of 40° C. or higher and lower than a boiling point thereof, more preferably from 50° C. to 90° C., and especially preferably from 70° C. to 90° C. So far as the temperature of the etchant is 40° C. or higher, the etching rate does not become excessively low so that the production efficiency is not remarkably lowered. On the other hand, so far as the temperature is lower than the boiling point, a change of the liquid composition is suppressed so that the etching condition can be kept on a fixed level. By making the temperature of the etchant high, the etching rate increases. However, taking into consideration suppression of a change of the composition of the etchant on a small level or the like, an optimal treatment temperature may be properly determined.

The object of the etching treatment in the present invention is a monocrystalline silicon-containing substrate or polyhedral block, and the monocrystalline silicon is present in an entire region or partial region of the substrate or block. In this connection, the monocrystalline silicon may be of a single layer or may be laminated in a multi-layered state. A material obtained by subjecting an entire region or partial region of such a substrate or block to ion doping is also the object of the etching treatment. Also, those in which a material such as a silicon oxide film, a silicon nitride film, a silicon organic film, etc. or a metal film such as an aluminum film, a chromium film, a gold film, etc. is present on the surface of the foregoing etching object or in the inside of the object are included in the object of the etching treatment in the present invention.

### EXAMPLES

The present invention is more specifically described below with reference to the following Examples and Comparative Examples, but it should be construed that the present invention is not limited to these Examples at all. The etching object used for the evaluation is a monocrystalline silicon (100) (hereinafter sometimes simply referred to as “silicon (100)”) wafer. The surface on one side of this silicon (100) wafer is in a state where its entire surface is covered by a protective film made of a silicon thermal oxide film; and the surface on the other side has a pattern shape in which a part of a silicon thermal oxide film is removed by dry etching, whereby the silicon surface is exposed. This silicon (100) wafer was immersed in a 1% hydrofluoric acid aqueous solution at 23° C. for 7 minutes just before an etching treatment and then rinsed with ultra-pure water, followed by drying. A silicon natural oxide film formed on the surface of a portion where the silicon surface in a pattern shape was exposed was removed by this treatment with a hydrofluoric acid aqueous solution, and thereafter, the etching treatment was carried out.

Etching Treatment Method of Monocrystalline silicon {100} Wafer and Calculation Method of Etching Rate

Each of etchants shown in the following Examples and Comparative Examples was charged in a container made of PTFE (polytetrafluoroethylene), this container was dipped in a water bath, and the temperature of the etchant was increased to 80° C. After the temperature of the etchant reached 80° C., a monocrystalline silicon {100} wafer was subjected to an etching treatment upon being dipped in the etchant for 10 minutes; and thereafter, the wafer was taken out, rinsed with ultra-pure water and then dried. In the wafer having been subjected to an etching treatment, following the etching of silicon, the pattern portion became in a recessed state as compared with the surroundings thereof, and a difference of elevation between the etched portion and the non-etched portion was measured, thereby determining an etching depth of the silicon {100} face for 10 minutes. A value obtained by dividing this etching depth by 10 was calculated as an etching rate (unit: μm/min) of the silicon {100} face.

### Heat Aging Test Method and Lowering Ratio of Etching Rate

A heat aging test was carried out according to the following method. That is, after measuring an etching rate (V₁) of the silicon {100} face at an etching temperature of 80° C., this temperature of the etchant was raised to 85° C.; the warmed state of 85° C. was continued for 24 hours; thereafter, the liquid temperature was returned to 80° C.; and an etching rate (V₂) of the silicon {100} face at 80° C. was again measured. The etching rate before and after this heat aging treatment was compared, and a value obtained by dividing a difference in the etching rate before and after the heat aging treatment (V₁−V₂) by the etching rate (V₁) before the heat aging treatment, followed by multiplication by 100 was calculated as a lowering ratio of etching rate (expression 1)

Lowering ratio of etching rate (%)=[(V₁−V₂)/(V₁)]×100 (1)

The heat aging treatment performed in each of Examples 1 to 9 and Comparative Examples 1 to 4 is merely an example of the treatment performed for the purpose of evaluating the stability of the etchant. Needless to say, the higher the heating temperature or the longer the heating time, the more the decomposition of hydroxylamine proceeds, whereby the lowering of the etching rate becomes conspicuous; and the lower the heating temperature or the shorter the heating time, the more the lowering of the etching rate is reduced. This test is made for the purpose of relatively comparing a degree of the lowering of the etching rate of the silicon {100} face among the respective liquid compositions.

### pH Measurement

The pH measurement was carried out at 23° C. using a pH meter (Model: F-12), manufactured by Horiba, Ltd.

In the Examples of the present invention, the tetramethylammonium and tetramethylammonium hydrogencarbonate added in the etchant are TMAC (a trade name), manufactured by Tama Chemicals Co., Ltd. As a result of analysis using an automatic titrator (Model: GT-100, manufactured by Mitsubishi Chemical Corporation), it was noted that the subject TMAC contained 18.3% of tetramethylammonium carbonate and 40.3% of tetramethylammonium hydrogencarbonate. In this connection, in the measurement using the automatic titrator, following the dropping of a 0.1 M HCl standard solution, the pH is measured, and a titration curve is automatically plotted. The titration curve exhibits a two-stage pH change in Examples, and each concentration can be determined from a dropping amount (vo1) up to a first end point and a dropping amount (vo2) up to a second end point. A method of determining each concentration in an aqueous solution of a mixture of a carbonate and a hydrogencarbonate from vo1 and vo2 is generally known and is described in, for example, Bunseki Kagaku Jikken (Experiments for Analytical Chemistry), 1986, Shokabo Publishing Co., Ltd., p.110.

### Example 1

276 g of a 25% by weight tetramethylammonium hydroxide (TMAH) aqueous solution (containing TMAH in an amount corresponding to 0.76 moles), 93 g of TMAC (containing [{(CH₃)₄N}₂CO₃] in an amount corresponding to 0.08 moles and [{(CH₃)₄N}HCO₃] in an amount corresponding to 0.28 moles), 200 g of a 50% by weight hydroxylamine (HA) aqueous solution and 431 g of water were mixed to prepare 1,000 g of an etchant. A tetramethylammonium ion concentration and a total sum of carbonate ion and hydrogencarbonate ion concentrations in this etchant are calculated to be 1.20 moles/kg and 0.36 moles/kg, respectively, and a molar ratio of the total sum of the carbonate ion and hydrogencarbonate ion concentrations to the tetramethylammonium ion concentration is 0.30. An HA concentration in this etchant is 10% by weight, and a pH of this etchant is 13.7.

The heat aging test was carried out using this etchant. As a result, V₁ was 1.44 μm/min, V₂ was 1.26 μm/min, and the lowering ratio of etching rate was 12.5%.

### Example 2

391 g of a 25% by weight TMAH aqueous solution (containing TMAH in an amount corresponding to 1.07 moles), 132 g of TMAC (containing [{(CH₃)₄N}₂CO₃] in an amount corresponding to 0.12 moles and [{(CH₃)₄N}HCO₃] in an amount corresponding to 0.39 moles), 200 g of a 50% by weight hydroxylamine (HA) aqueous solution and 278 g of water were mixed to prepare 1,000 g of an etchant. A tetramethylammonium ion concentration and a total sum of carbonate ion and hydrogencarbonate ion concentrations in this etchant are calculated to be 1.70 moles/kg and 0.51 moles/kg, respectively, and a molar ratio of the total sum of the carbonate ion and hydrogencarbonate ion concentrations to the tetramethylammonium ion concentration is 0.30. An HA concentration in this etchant is 10% by weight, and a pH of this etchant is 13.9 or more.

The heat aging test was carried out using this etchant. As a result, V₁ was 1.36 μm/min, V₂ was 1.18 μm/min, and the lowering ratio of etching rate was 13.2%.

### Example 3

505 g of a 25% by weight TMAH aqueous solution (containing TMAH in an amount corresponding to 1.39 moles), 171 g of TMAC (containing [{(CH₃)₄N}₂CO₃] in an amount corresponding to 0.15 moles and [{(CH₃)₄N}HCO₃] in an amount corresponding to 0.51 moles), 200 g of a 50% by weight hydroxylamine (HA) aqueous solution and 124 g of water were mixed to prepare 1,000 g of an etchant. A tetramethylammonium ion concentration and a total sum of carbonate ion and hydrogencarbonate ion concentrations in this etchant are calculated to be 2.20 moles/kg and 0.66 moles/kg, respectively, and a molar ratio of the total sum of the carbonate ion and hydrogencarbonate ion concentrations to the tetramethylammonium ion concentration is 0.30. An HA concentration in this etchant is 10% by weight, and a pH of this etchant is 13.9 or more.

The heat aging test was carried out using this etchant. As a result, V₁ was 1.27 μm/min, V₂ was 1.09 μm/min, and the lowering ratio of etching rate was 14.2%.

### Example 4

222 g of a 25% by weight TMAH aqueous solution (containing TMAH in an amount corresponding to 0.61 moles), 124 g of TMAC (containing [{(CH₃)₄N}₂CO₃] in an amount corresponding to 0.11 moles and [{(CH₃)₄N}HCO₃] in an amount corresponding to 0.37 moles), 200 g of a 50% by weight hydroxylamine (HA) aqueous solution and 454 g of water were mixed to prepare 1,000 g of an etchant. Atetramethylammonium ion concentration and a total sum of carbonate ion and hydrogencarbonate ion concentrations in this etchant are calculated to be 1.20 moles/kg and 0.48 moles/kg, respectively, and a molar ratio of the total sum of the carbonate ion and hydrogencarbonate ion concentrations to the tetramethylammonium ion concentration is 0.40. An HA concentration in this etchant is 10% by weight, and a pH of this etchant is 13.4.

The heat aging test was carried out using this etchant. As a result, V₁ was 1.44 μm/min, V₂ was 1.28 μm/min, and the lowering ratio of etching rate was 11.1%.

### Example 5

315 g of a 25% by weight TMAH aqueous solution (containing TMAH in an amount corresponding to 0.87 moles), 176 g of TMAC (containing [{(CH₃)₄N}₂CO₃] in an amount corresponding to 0.15 moles and [{(CH₃)₄N}HCO₃] in an amount corresponding to 0.53 moles), 200 g of a 50% by weight hydroxylamine (HA) aqueous solution and 309 g of water were mixed to prepare 1,000 g of an etchant. A tetramethylammonium ion concentration and a total sum of carbonate ion and hydrogencarbonate ion concentrations in this etchant are calculated to be 1.70 moles/kg and 0.68 moles/kg, respectively, and a molar ratio of the total sum of the carbonate ion and hydrogencarbonate ion concentrations to the tetramethylammonium ion concentration is 0.40. An HA concentration in this etchant is 10% by weight, and a pH of this etchant is 13.8.

The heat aging test was carried out using this etchant. As a result, V₁ was 1.38 μm/min, V₂ was 1.23 μm/min, and the lowering ratio of etching rate was 10.9%.

### Example 6

407 g of a 25% by weight TMAH aqueous solution (containing TMAH in an amount corresponding to 1.12 moles), 228 g of TMAC (containing [{(CH₃)₄N}₂CO₃] in an amount corresponding to 0.20 moles and [{(CH₃)₄N}HCO₃] in an amount corresponding to 0.68 moles), 200 g of a 50% by weight hydroxylamine (HA) aqueous solution and 165 g of water were mixed to prepare 1,000 g of an etchant. A tetramethylammonium ion concentration and a total sum of carbonate ion and hydrogencarbonate ion concentrations in this etchant are calculated to be 2.20 moles/kg and 0.88 moles/kg, respectively, and a molar ratio of the total sum of the carbonate ion and hydrogencarbonate ion concentrations to the tetramethylammonium ion concentration is 0.40. An HA concentration in this etchant is 10% by weight, and a pH of this etchant is 13.9 or more.

The heat aging test was carried out using this etchant. As a result, V₁ was 1.33 μm/min, V₂ was 1.18 μm/min, and the lowering ratio of etching rate was 11.3%.

### Comparative Example 1

436 g of a 25% by weight TMAH aqueous solution (containing TMAH in an amount corresponding to 1.20 moles), 200 g of a 50% by weight hydroxylamine (HA) aqueous solution and 364 g of water were mixed to prepare 1,000 g of an etchant. A tetramethylammonium ion concentration in this etchant is calculated to be 1.20 moles/kg; and this etchant does not contain a carbonate ion and a hydrogencarbonate ion, and therefore, a molar ratio of a total sum of the carbonate ion and hydrogencarbonate ion concentrations to the tetramethylammonium ion concentration is 0. An HA concentration in this etchant is 10% by weight, and a pH of this etchant is 13.9 or more.

The heat aging test was carried out using this etchant. As a result, V₁ was 1.38 μm/min, V₂ was 1.05 μm/min, and the lowering ratio of etching rate was 23.9%.

### Comparative Example 2

618 g of a 25% by weight TMAH aqueous solution (containing TMAH in an amount corresponding to 1.70 moles), 200 g of a 50% by weight hydroxylamine (HA) aqueous solution and 182 g of water were mixed to prepare 1,000 g of an etchant. A tetramethylammonium ion concentration in this etchant is calculated to be 1.70 moles/kg; and this etchant does not contain a carbonate ion and a hydrogencarbonate ion, and therefore, a molar ratio of a total sum of the carbonate ion and hydrogencarbonate ion concentrations to the tetramethylammonium ion concentration is 0. An HA concentration in this etchant is 10% by weight, and a pH of this etchant is 13.9 or more.

The heat aging test was carried out using this etchant. As a result, V₁ was 1.18 μm/min, V₂ was 0.91 μm/min, and the lowering ratio of etching rate was 22.9%.

### Comparative Example 3

800 g of a 25% by weight TMAH aqueous solution (containing TMAH in an amount corresponding to 2.20 moles) and 200 g of a 50% by weight hydroxylamine (HA) aqueous solution were mixed to prepare 1,000 g of an etchant. A tetramethylammonium ion concentration in this etchant is calculated to be 2.20 moles/kg; and this etchant does not contain a carbonate ion and a hydrogencarbonate ion, and therefore, a molar ratio of a total sum of the carbonate ion and hydrogencarbonate ion concentrations to the tetramethylammonium ion concentration is 0. An HA concentration in this etchant is 10% by weight, and a pH of this etchant is 13.9 or more.

The heat aging test was carried out using this etchant As a result, V₁ was 0.98 μm/min, V₂ was 0.77 μm/min, and the lowering ratio of etching rate was 21.4%.

### Example 7

618 g of a 25% by weight TMAH aqueous solution (containing TMAH in an amount corresponding to 1.70 moles) and 200 g of a 50% by weight hydroxylamine (HA) aqueous solution were mixed. A whole amount of 12.4 L (at 23° C., 1 atm) of a CO₂ gas (this is corresponding to 0.51 moles of CO₂) was absorbed in this aqueous solution in a closed system. Water was further added to prepare 1,000 g of an etchant. A tetramethylammonium ion concentration and a total sum of CO₂, carbonate ion and hydrogencarbonate ion concentrations in this etchant are calculated to be 1.70 moles/kg and 0.51 moles/kg, respectively, and a molar ratio of the total sum of the CO₂, carbonate ion and hydrogencarbonate ion concentrations to the tetramethylammonium ion concentration is 0.30. An HA concentration in this etchant is 10% by weight, and a pH of this etchant is 13.9 or more.

The heat aging test was carried out using this etchant. As a result, V₁ was 1.35 μm/min, V₂ was 1.17 μm/min, and the lowering ratio of etching rate was 13.3%.

### Example 8

618 g of a 25% by weight TMAH aqueous solution (containing TMAH in an amount corresponding to 1.70 moles) and 200 g of a 50% by weight hydroxylamine (HA) aqueous solution were mixed. A whole amount of 16.5 L (at 23° C., 1 atm) of a CO₂ gas was absorbed in this aqueous solution in a closed system. On that occasion, an increased weight was 29.9 g (corresponding to 0.68 moles). Water was further added to prepare 1,000 g of an etchant. A tetramethylammonium ion concentration and a total sum of CO₂, carbonate ion and hydrogencarbonate ion concentrations in this etchant are calculated to be 1.70 moles/kg and 0.68 moles/kg, respectively, and a molar ratio of the total sum of the CO₂, carbonate ion and hydrogencarbonate ion concentrations to the tetramethylammonium ion concentration is 0.40. An HA concentration in this etchant is 10% by weight, and a pH of this etchant is 13.8.

The heat aging test was carried out using this etchant. As a result, V₁ was 1.37 μm/min, V₂ was 1.22 μm/min, and the lowering ratio of etching rate was 10.9%.

### Comparative Example 4

618 g of a 25% by weight TMAH aqueous solution (containing TMAH in an amount corresponding to 1.70 moles) and 200 g of a 50% by weight hydroxylamine (HA) aqueous solution were mixed. A whole amount of 20.6 L (at 23° C., 1 atm) of a CO₂ gas was absorbed in this aqueous solution in a closed system. On that occasion, an increased weight was 37.4 g (corresponding to 0.85 moles). Water was further added to prepare 1,000 g of an etchant. A tetramethylammonium ion concentration and a total sum of CO₂, carbonate ion and hydrogencarbonate ion concentrations in this etchant are calculated to be 1.70 moles/kg and 0.85 moles/kg, respectively, and a molar ratio of the total sum of the CO₂, carbonate ion and hydrogencarbonate ion concentrations to the tetramethylammonium ion concentration is 0.50. An HA concentration in this etchant is 10% by weight, and a pH of this etchant is 12.5 or more.

The etching treatment of silicon was carried out using this etchant. However, silicon was not dissolved, so that it could not be etched.

### Example 9

466 g of a 25% by weight TMAH aqueous solution (containing TMAH in an amount corresponding to 1.28 moles), 88 g of TMAC (containing [{(CH₃)₄N}₂CO₃] in an amount corresponding to 0.08 moles and [{(CH₂)₄N}HCO₂] in an amount corresponding to 0.26 moles) and 200 g of a 50% by weight hydroxylamine (HA) aqueous solution were mixed. A whole amount of 8.3 L (at 23° C., 1 atm) of a CO₂ gas was absorbed in this aqueous solution in a closed system. On that occasion, an increased weight was 15.0 g (corresponding to 0.34 moles). Water was further added to prepare 1,000 g of an etchant. A tetramethylammonium ion concentration and a total sum of CO₂, carbonate ion and hydrogencarbonate ion concentrations in this etchant are calculated to be 1.70 moles/kg and 0.68 moles/kg, respectively, and a molar ratio of the total sum of the CO₂, carbonate ion and hydrogencarbonate ion. concentrations to the tetramethylammonium ion concentration is 0.40. An HA concentration in this etchant is 10% by weight, and a pH of this etchant is 13.8.

The heat aging test was carried out using this etchant. As a result, V₁ was 1.39 μm/min, V₂ was 1.24 μm/min, and the lowering ratio of etching rate was 10.8%.

It is noted from Examples 1 to 9 and Comparative Examples 1 to 4 that by using an alkaline aqueous solution containing (A) tetramethylammonium hydroxide, (B) hydroxylamine and (C) carbon dioxide (CO₂) and/or a carbonic acid salt of tetramethylammonium and having a pH of 13 or more as silicon etchant, a lowering of the silicon etching rate by the heat aging test is suppressed.

The results of the Examples and Comparative Examples are shown in Table 1.

TABLE 1

| | | | | | | | Etching rate | |
|---|---|---|---|---|---|---|---|---|
| | | Added | | | | pH | V₁ before | Lowering |
| | | water-soluble | | | | measured | heat aging | ratio of |
| | | carbonate | Tc | Cc | | value of | treatment | etching rate |
| | | compound | (mole/kg) | (mole/kg) | Cc/Tc | solution | (μm/min) | (%) |
| Example | 1 | TMAC | 1.2 | 0.36 | 0.30 | 13.7 | 1.44 | 12.5 |
| | 2 | TMAC | 1.7 | 0.51 | 0.30 | 13.9 or more | 1.36 | 13.2 |
| | 3 | TMAC | 2.2 | 0.66 | 0.30 | 13.9 or more | 1.27 | 14.2 |
| | 4 | TMAC | 1.2 | 0.48 | 0.40 | 13.4 | 1.44 | 11.1 |
| | 5 | TMAC | 1.7 | 0.68 | 0.40 | 13.8 | 1.38 | 10.9 |
| | 6 | TMAC | 2.2 | 0.88 | 0.40 | 13.9 or more | 1.33 | 11.3 |
| | 7 | CO₂ | 1.7 | 0.51 | 0.30 | 13.9 or more | 1.35 | 13.3 |
| | 8 | CO₂ | 1.7 | 0.68 | 0.40 | 13.8 | 1.37 | 10.9 |
| | 9 | TMAC + CO₂ | 1.7 | 0.68 | 0.40 | 13.8 | 1.39 | 10.8 |
| Comparative | 1 | — | 1.2 | 0.00 | 0.00 | 13.9 or more | 1.38 | 23.9 |
| Example | 2 | — | 1.7 | 0.00 | 0.00 | 13.9 or more | 1.18 | 22.9 |
| | 4 | — | 2.2 | 0.00 | 0.00 | 13.9 or more | 0.98 | 21.4 |
| | 5 | CO₂ | 1.7 | 0.85 | 0.50 | 11.9 | — | Calculation |
| | | | | | | | | impossible *¹ |

Immersion temperature: 80° C.
Immersion time: 10 minutes
TMAC: Mixed aqueous solution of tetramethylammonium carbonate and tetramethylammonium hydrogencarbonate
CO₂: Carbon dioxide
Tc: Tetramethylammonium ion concentration
Cc: Total sum of carbon dioxide, carbonate ion and hydrogencarbonate ion concentrations
*¹: Impossible for calculating the lowering ratio of etching rate because the etching rate (V₁) before the heat aging treatment is not more than the detection limit (0.1 μm/min).

### INDUSTRIAL APPLICABILITY

According to the silicon etchant and the silicon etching method of the present invention, complicated operations such as frequent processing shape confirmation in realizing a long life of the hydroxylamine-containing silicon etchant and performing an etching treatment, and the like can be greatly simplified. Utilizing this effect, the silicon etchant and the silicon etching method of the present invention can be suitably used for manufacturing parts or semiconductor devices which are used for micromachines.

1. A silicon etchant, comprising:
an alkaline aqueous solution comprising
(A) tetramethylammonium hydroxide,
(B) hydroxylamine and
(C) at least one of carbon dioxide (CO₂) and a carbonic acid salt of tetramethylammonium,
wherein the alkaline aqueous solution has a pH of 13 or more.

2. The silicon etchant according to claim 1, wherein the carbonic acid salt of tetramethylammonium (C) is at least one of tetramethylammonium carbonate [{(CH₃)₄N}₂CO₃] and tetramethylammonium hydrogencarbonate [{(CH₃)₄N}HCO₃].

3. The silicon etchant according to claim 1, wherein
an amount of a tetramethylammonium ion {(CH₃)₄N⁺} derived from the tetramethylammonium hydroxide (A) and the carbonic acid salt of tetramethylammonium (C) comprised in the silicon etchant is in the range of from 1.0 mole to 2.4 moles per kg of the silicon etchant; and
a total sum of a carbonate ion (CO₃²⁻) and a hydrogencarbonate ion (HCO₃⁻) derived from the carbon dioxide (CO₂) and carbonic acid salt of tetramethylammonium (C) is in the range of from 0.28 to 0.42 in terms of a molar ratio relative to the amount of the tetramethylammonium ion.

4. The silicon etchant according to claim 2, wherein a pH is 13.3 or more.

5. A silicon etching method, comprising:
contacting a silicon etchant with an etching object,
wherein the silicon etchant comprising
an alkaline aqueous solution comprising
(A) tetramethylammonium hydroxide,
(B) hydroxylamine and
(C) at least one of carbon dioxide (CO₂) and a carbonic acid salt of tetramethylammonium, and
the alkaline aqueous solution has a pH of 13 or more.

6. The silicon etching method according to claim 5, comprising
bringing the alkaline aqueous solution and the etching object into contact with each other.

7. The silicon etching method according to claim 5, wherein the carbonic acid salt of tetramethylammonium (C) is at least one of tetramethylammonium carbonate [{(CH₃)₄N}₂CO₃] and tetramethylammonium hydrogencarbonate [{(CH₃)₄N}HCO₃].

8. The silicon etchant according to claim 1, comprising
(C) carbon dioxide (CO₂) and a carbonic acid salt of tetramethylammonium.

9. The silicone etchant according to claim 1, comprising
(C) carbon dioxide (CO₂).

10. The silicon etchant according to claim 1, comprising
(C) a carbonic acid salt of tetramethylammonium.

11. The silicon etchant according to claim 2, wherein the carbonic acid salt of tetramethylammonium (C) is tetramethylammonium carbonate [{(CH₃)₄N}₂CO₃] and tetramethylammonium hydrogencarbonate [{(CH₃)₄N}HCO₃].

12. The silicon etchant according to claim 2, wherein the carbonic acid salt of tetramethylammonium (C) is tetramethylammonium carbonate [{(CH₃)₄N}₂CO₃].

13. The silicon etchant according to claim 2, wherein the carbonic acid salt of tetramethylammonium (C) is tetramethylammonium hydrogencarbonate [{(CH₃)₄N}HCO₃].

14. The silicon etchant according to claim 5, comprising
(C) carbon dioxide (CO₂) and a carbonic acid salt of tetramethylammonium.

15. The silicon etchant according to claim 5, comprising
(C) carbon dioxide (CO₂).

16. The silicon etchant according to claim 5, comprising
(C) a carbonic acid salt of tetramethylammonium.

17. The silicon etching method according to claim 7, wherein the carbonic acid salt of tetramethylammonium (C) is tetramethylammonium carbonate [{(CH₃)₄N}₂CO₃] and tetramethylammonium hydrogencarbonate [{(CH₃)₄N}HCO₃].

18. The silicon etching method according to claim 7, wherein the carbonic acid salt of tetramethylammonium (C) is tetramethylammonium carbonate [{(CH₃)₄N}₂CO₃].

19. The silicon etching method according to claim 7, wherein the carbonic acid salt of tetramethylammonium (C) is tetramethylammonium hydrogencarbonate [{(CH₃)₄N}HCO₃].

20. The silicon etchant according to claim 3, wherein a pH is 13.3 or more.
